(19) United States
(12) Patent Application Publication
(10) Pub. No.: US 2025/0287683 A1
(43) Pub. Date: Sep. 11, 2025

(54) SEMICONDUCTOR DEVICE

(71) Applicant: Mitsubishi Electric Corporation, Tokyo (JP)

(72) Inventors: Yutaka TANIGUCHI, Tokyo (JP); Naoto KAGUCHI, Tokyo (JP); Kenji SUZUKI, Tokyo (JP); Tomohito KUDO, Tokyo (JP)

(73) Assignee: Mitsubishi Electric Corporation, Tokyo (JP)

(21) Appl. No.: 18/977,026

(22) Filed: Dec. 11, 2024

(30) Foreign Application Priority Data
Mar. 11, 2024 (JP) 2024-037300

(51) Int. Cl. H10D 84/00; H10D 62/10; H10D 62/832; H10D 64/00

(52) U.S. Cl. CPC H10D 84/161; H10D 62/107; H10D 62/8325; H10D 64/111

(57) ABSTRACT

An object is to provide a semiconductor device whose flexibility of assembly can be increased. A semiconductor device includes a semiconductor substrate having a rectangular active region in a top view, and a termination region around the active region, and includes: a gate electrode on an upper surface of the semiconductor substrate in the active region; and a gate line formed above the upper surface of the semiconductor substrate in the termination region and being electrically connected to the gate electrode, wherein the gate line is rectangular in a top view, and surrounds the active region, the gate line includes a gate pad portion for connecting the gate electrode to an external portion through bonding, and the gate pad portion is disposed on an entirety of at least one side of the gate line.

### BACKGROUND OF THE INVENTION

### Field of the Invention

The present disclosure relates to a semiconductor device.

### Description of the Background Art

Japanese Patent Application Laid-Open No. 2022-178755 discloses a semiconductor device including a gate electrode wire electrically connected to gate electrodes, and a gate electrode pad that is connected to the gate electrode wire and that is a region for connecting the respective gate electrodes to an external portion through bonding.

In the semiconductor device described in Japanese Patent Application Laid-Open No. 2022-178755, the region with the gate electrode pad is limited to one portion with respect to the entire perimeter of the semiconductor device. In other words, since a region in which bonding is possible is limited with respect to the entire perimeter of the semiconductor device, the semiconductor device has a constraint in assembly.

The present disclosure has been conceived to solve the aforementioned problem, and has an object of providing a semiconductor device whose flexibility of assembly can be increased by increasing a region in which bonding is possible, with respect to the entire perimeter of the semiconductor device.

### SUMMARY

The present disclosure has been conceived in view of the problem, and has an object of providing a semiconductor device whose flexibility of assembly can be increased by increasing a region in which bonding is possible, with respect to the entire perimeter of the semiconductor device.

A semiconductor device includes a semiconductor substrate having an active region that is rectangular in a top view, and a termination region around the active region, and includes: a gate electrode formed on an upper surface of the semiconductor substrate in the active region; and a gate line formed above the upper surface of the semiconductor substrate in the termination region, the gate line being electrically connected to the gate electrode, wherein the gate line is rectangular in a top view, and surrounds the active region, the gate line includes a gate pad portion for connecting the gate electrode to an external portion through bonding, and the gate pad portion is disposed on an entirety of at least one side of the gate line.

This can increase flexibility of assembling a semiconductor device.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic top view of a semiconductor device according to Embodiment 1;

FIG. 2 is a schematic top view of the semiconductor device according to Embodiment 1;

FIG. 3 is a schematic cross-sectional view of A-A in FIG. 1 of the semiconductor device according to Embodiment 1;

FIG. 4 is a schematic top view of the semiconductor device according to Embodiment 1;

FIG. 5 is a schematic top view of a related semiconductor device;

FIG. 6 is a schematic top view of a semiconductor device according to Embodiment 2;

FIG. 7 is a schematic cross-sectional view of A-A in FIG. 6 of the semiconductor device according to Embodiment 2;

FIG. 8 is a schematic top view of a semiconductor device according to a modification of

### Embodiment 2; and

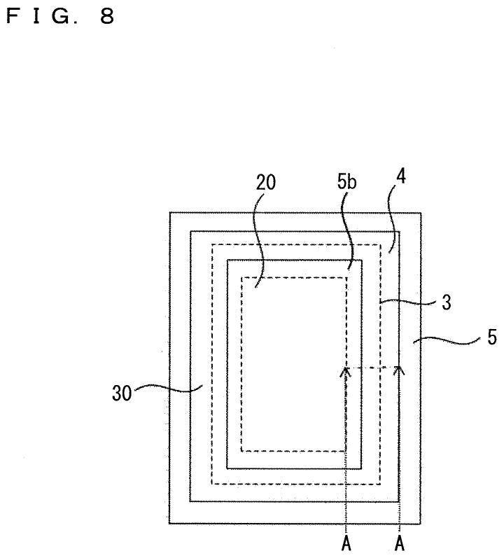

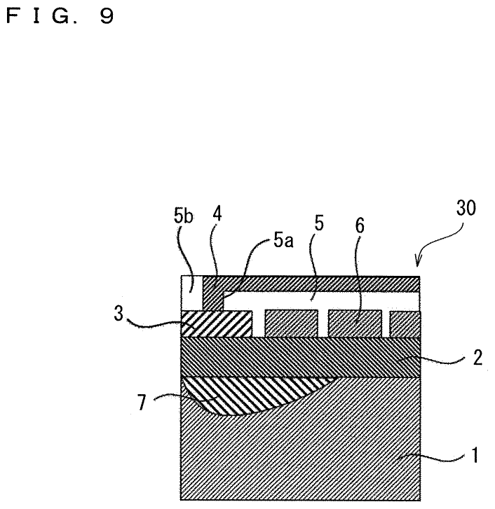

FIG. 9 is a schematic cross-sectional view of A-A in FIG. 8 of the semiconductor device according to the modification of Embodiment 2.

### DESCRIPTION OF THE PREFERRED EMBODIMENTS

### Introduction

In the following description, n-type and p-type denote semiconductor conductivity types. Although the first conductivity type is described as n-type and the second conductivity type is described as p-type in the present disclosure, the first conductivity type may be p-type and the second conductivity type may be n-type. Furthermore, n⁻ type represents an impurity concentration lower than that of n-type, and n⁺ type represents an impurity concentration higher than that of n-type. Similarly, p-type represents an impurity concentration lower than that of p-type, and p⁺ type represents an impurity concentration higher than that of p-type.

One side in a direction parallel to a height direction of a semiconductor device will be referred to as “upper”, and the other side will be referred to as “lower”. One of two main surfaces of a substrate, a layer, or another component will be referred to as an “upper surface”, and the other surface will be referred to as a “lower surface”. The directions of “up” and “down” are not limited to the direction of gravity or a direction in which the semiconductor device is mounted.

For convenience of the description, a width direction of a semiconductor device will be described as an X direction, a depth direction of the semiconductor device which is orthogonal to the X direction will be described as a Y direction, and a thickness direction or a height direction of the semiconductor device, that is, a direction normal to an XY plane will be described as a Z direction.

Since the drawings are schematically illustrated, the mutual relationships in size and position between images in different drawings are not necessarily accurate but may be changed when needed. In the following description, the same reference numerals are assigned to the same constituent elements, and their names and functions are the same. Thus, the detailed description thereof may be omitted.

### Embodiment 1

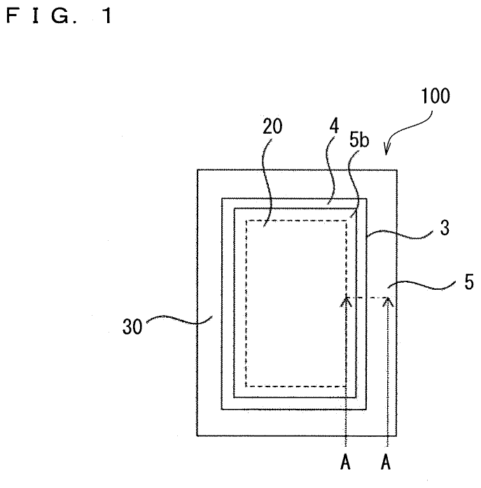

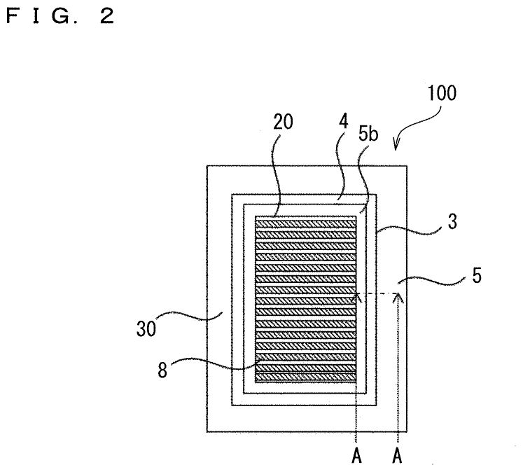

Embodiment 1 will be hereafter described with reference to the drawings. FIG. 1 is a schematic top view schematically illustrating a top structure of the entirety of a semiconductor device 100 according to Embodiment 1. A dotted line in FIG. 1 represents a gate line 3 covered with a protective film 5. FIG. 2 omits the illustration of the protective film 5 on an active region 20 from the schematic top view according to Embodiment 1. As illustrated in FIG. 1, the semiconductor device 100 includes the active region 20 having a rectangular shape in a top view, and a termination region 30 around the active region 20. The rectangular shape is not limited to an exactly rectangular shape but may be a roughly rectangular shape as a whole, and includes, for example, a roughly rectangular shape with four round corners. The active region 20 includes semiconductor switching elements. The active region 20 may include, as the semiconductor switching elements, an insulated-gate bipolar transistor (hereinafter abbreviated as IGBT), and a reverse-conducting IGBT (RC-IGBT) including an IGBT region and a diode region in one semiconductor switching element. The termination region 30 is provided for retaining the withstanding voltage of the semiconductor device 100.

As illustrated in FIG. 1, the gate line 3 is disposed in the termination region 30 to surround the active region 20. Since the active region 20 is rectangular in a top view in Embodiment 1, the gate line 3 is also rectangular in a top view. As illustrated in FIG. 2, the active region 20 includes gate electrodes 8. The gate electrodes 8 are formed above an upper surface of a semiconductor substrate 1 to be described later, and are electrically connected to the gate line 3. Furthermore, the gate electrodes 8 may be trench gate electrodes 8 arranged in stripes as illustrated in FIG. 2. Since a method for connecting the gate line 3 to the gate electrodes 8 is identical to a conventional method, the detailed description is omitted. For example, when the gate electrodes 8 are arranged in stripes as illustrated in FIG. 2, both ends of each of the gate electrodes 8 may be physically connected to the gate line 3. Alternatively, the gate line 3 may be a primary gate line, and secondary gate lines may be drawn from the primary gate line 3 toward the active region 20. The secondary gate lines may be physically connected to the respective gate electrodes 8. This can electrically connect the gate line 3 to the respective gate electrodes 8. A detailed structure of the semiconductor device 100 according to Embodiment 1 will be hereinafter described based on FIGS. 1, 3, and 4. Since a detailed structure of the active region 20 of the semiconductor device 100 is a conventional structure, the description is omitted. Furthermore, since a detailed structure of a lower surface of the semiconductor substrate 1 in the termination region 30 of the semiconductor device 100 is a conventional structure, the description is omitted.

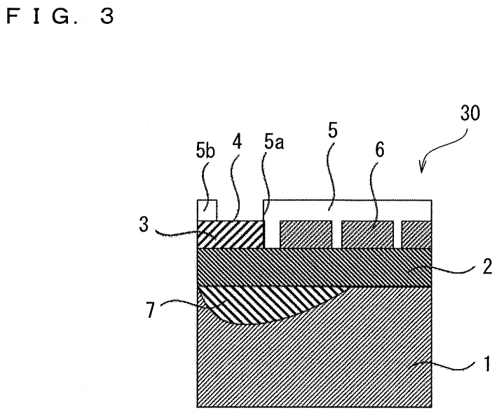

FIG. 3 is a cross-sectional view of the termination region 30 of the semiconductor device 100 according to Embodiment 1 in a direction orthogonal to an extension direction of the gate line 3. FIG. 3 illustrates a cross-sectional view taken along an alternate long and short dashed line A-A in FIG. 1. A cross-sectional structure of the semiconductor device 100 will be described with reference to FIG. 3. As illustrated in FIG. 3, the semiconductor device 100 includes the semiconductor substrate 1, and the gate line 3 and a gate pad portion 4 in the termination region 30.

The semiconductor substrate 1 includes the active region 20 and the termination region 30 which are described above. The semiconductor substrate 1 includes an n-type drift layer. Furthermore, the semiconductor substrate 1 is made of various semiconductor materials, for example, silicon (Si), silicon carbide (SiC), and gallium nitride (GaN).

The gate line 3 is disposed above the upper surface of the semiconductor substrate 1 in the termination region 30. An insulating film 2 may be disposed between the semiconductor substrate 1 and the gate line 3.

As illustrated in FIG. 3, field plates 6 may be disposed above the upper surface of the semiconductor substrate 1. The field plates 6 are disposed at intervals to prevent interference with the gate line 3. A VLD 7 may be disposed on the upper surface of the semiconductor substrate 1 as illustrated in FIG. 3. The VLD 7 is generally-called variation of lateral doping (VLD) that surrounds the active region 20 with a p-type well layer with a concentration slope. Not limited to the field plates 6 or the VLD 7, a known withstanding voltage retention structure may be appropriately selected and disposed in the termination region 30.

As illustrated in FIG. 1, a protective film 5 is preferably disposed on the front surface of the active region 20 and the termination region 30. This can protect the front surface of the active region 20 and the termination region 30. As illustrated in FIGS. 1 and 3, a part of the protective film 5 on the gate line 3 in the termination region 30 is opened in Embodiment 1. The protective film 5 may be opened such that a protective film 5b remains in a region closer to the active region 20 out of a region on the gate line 3 as illustrated in FIGS. 1 and 3. This protective film 5b will be referred to as a first protective film 5b in the following description.

The gate pad portion 4 is disposed on the gate line 3. The gate pad portion 4 is disposed to connect the gate electrodes 8 to an external portion. Bonding is performed at the gate pad portion 4. In Embodiment 1, the gate pad portion 4 is the gate line 3 itself. As illustrated in FIGS. 1 and 2, it is preferred to form an opening 5a by opening a part of the protective film 5 on the front surface of the termination region 30 to allow the gate line 3 exposed by the opening 5a to function as the gate pad portion 4. As illustrated in FIG. 1, the gate pad portion 4 is disposed on an entirety of the four sides of the gate line 3. Since disposing the gate pad portion 4 on the entirety of the four sides of the gate line 3 enables wire bonding from anywhere within 360 degrees around the semiconductor device 100, flexibility of assembling the semiconductor device can be increased.

The gate line 3 exposed by the opening 5a is preferably sealed by a sealing resin after the bonding. This can protect the exposed gate line 3.

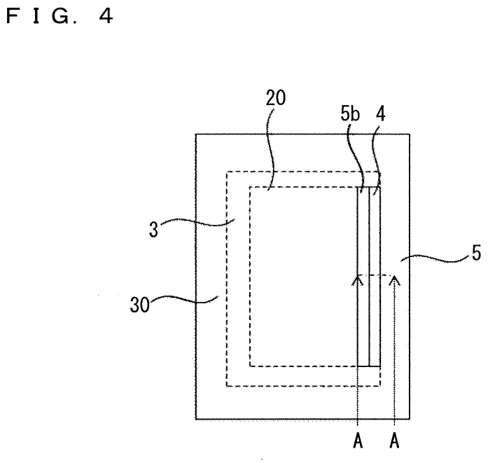

Although FIG. 1 illustrates an example of disposing the gate pad portion 4 on the entirety of the four sides of the gate line 3, the gate pad portion 4 need not be disposed on all the four sides but should be disposed on the entirety of at least one of the sides. FIG. 4 illustrates an example of disposing the gate pad portion 4 on the entirety of one side of the gate line 3. A dotted line in FIG. 4 represents the gate line 3 covered with the protective film 5. In the example of FIG. 4, the opening 5a is formed by opening the protective film 5 on the one side of the gate line 3 out of the protective film 5 formed on the front surface of the termination region 30 to allow only the one side of the gate line 3 exposed by the opening 5a to function as the gate pad portion 4. Since wire bonding is possible anywhere on the gate pad portion 4 disposed on the entirety of the one side of the gate line 3, flexibility of assembling the semiconductor device can be increased.

When the gate pad portion 4 is disposed on a part of the sides of the gate line 3, the side of the gate line 3 on which the gate pad portion 4 is not disposed does not function as a gate pad. Thus, the width of the side of the gate line 3 on which the gate pad portion 4 is not disposed may be less than that of the side of the gate line 3 on which the gate pad portion 4 is disposed. This can downsize the semiconductor device 100 more than semiconductor device in which the all sides of the gate line 3 are formed with the same width.

Although the gate pad portion 4 is disposed on the “entirety” of at least one of the sides of the gate line 3 in the aforementioned description, “entirety” does not necessarily mean the “entirety” in the strict sense. The gate pad portion 4 should be substantially formed over the entirety of one side of the gate line 3 to the extent that bonding positions can be flexibly selected from the formed gate pad portion 4. In other words, the gate pad portion 4 need not be partly formed on the one side of the gate line 3.

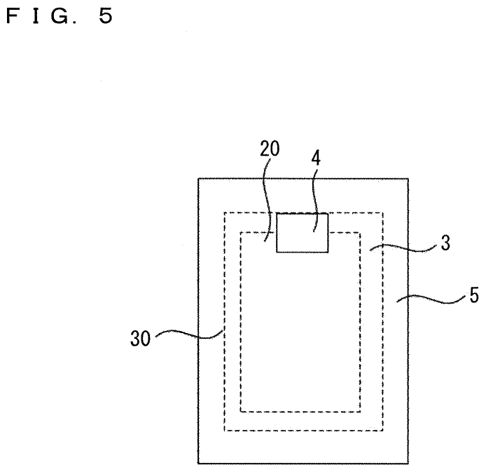

Here, FIG. 5 illustrates a related semiconductor device as a comparative example to be compared with the semiconductor device 100 according to Embodiment 1. Dotted lines in FIG. 5 represent the gate line 3 covered with the protective film 5. As illustrated in FIG. 5, a portion widened toward the center direction of the active region 20 on the gate line 3 is the gate pad portion 4 in the related semiconductor device, and the portion functions as a gate pad. A region immediately under the portion is an invalid region without any semiconductor switching element. As illustrated in FIG. 5, the active region 20 includes a recess due to the invalid region. Here, the active region 20 needs to be enlarged by the dimensions of the recess with respect to the dimensions of the semiconductor device to ensure the operating performance of the semiconductor device.

In contrast, since the active region 20 is rectangular in a top view and the gate line 3 is formed to surround the rectangular active region 20 in the semiconductor device 100 according to Embodiment 1, the active region 20 does not include any recess. Thus, the active region 20 need not be enlarged with respect to the dimensions of the semiconductor device. In other words, the semiconductor device 100 according to Embodiment 1 can reduce the active region 20 with respect to the dimensions of the semiconductor device more than related semiconductor devices, and can ensure the operating performance of the related semiconductor devices.

Furthermore, since the termination region 30 has a withstanding voltage retention structure for protecting the active region 20, the dimensions of the termination region 30 is generally formed relatively larger than that of the active region 20. Thus, there is no need to separately provide a region for forming a gate pad, even in a structure in which the active region 20 is rectangular and the gate line 3 is formed to surround the rectangular active region 20. Thus, since the aforementioned structure can reduce the active region 20 with respect to the dimensions of the semiconductor device, the structure can downsize the semiconductor device.

Next, a method of manufacturing the semiconductor device 100 according to Embodiment 1 will be described. The method of manufacturing the semiconductor device 100 according to Embodiment 1 is basically identical to conventional methods of manufacturing semiconductor devices. Since a gate line formation process and a gate pad portion formation process according to Embodiment 1 are basically identical to conventional manufacturing methods, the description of a part of the method will be omitted.

The method of manufacturing the semiconductor device 100 according to Embodiment 1 includes the gate line formation process and the gate pad portion formation process.

First, the gate line formation process will be described. In Embodiment 1, the gate line 3 is formed above the upper surface of the semiconductor substrate 1. Forming the gate line 3 wider than conventional ones allows the gate line 3 to function as a gate pad. The width of the gate line 3 should be large enough to enable bonding, and may be appropriately set according to, for example, the thickness of a bonding wire.

Next, the gate pad portion formation process will be described. A method of forming the opening 5a in the protective film 5 disposed on the front surface of the termination region 30 to form the gate pad portion 4 will be described as an example of the gate pad portion formation process. First, the protective film 5 is formed on the front surface of the termination region 30. The protective film 5 is formed in, for example, CVD. Next, the opening 5a is formed by etching a portion of the protective film 5 which is formed on the gate line 3. Forming the opening 5a to reach the upper surface of the gate line 3 exposes the gate line 3, and allows the exposed gate line 3 to function as the gate pad portion 4.

The protective film 5 on the entirety of one side of the gate line 3 is opened, so that the entirety of at least one side of the gate line 3 functions as the gate pad portion 4. It is preferred to open the protective film 5 on the entirety of the four sides of the gate line 3, so that the entirety of the four sides of the gate line 3 function as the gate pad portion 4.

As described above, disposing the gate pad portion 4 on the entirety of at least one side of the gate line 3 in the semiconductor device 100 according to Embodiment 1 can increase a region in which bonding is possible, with respect to the entire perimeter of the semiconductor device 100, and increase flexibility of assembling the semiconductor device.

### Embodiment 2

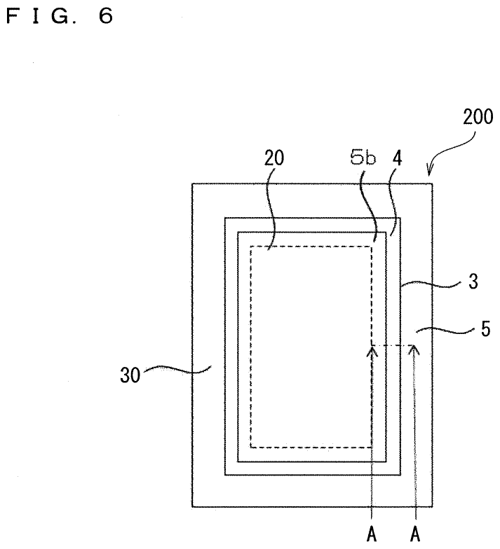

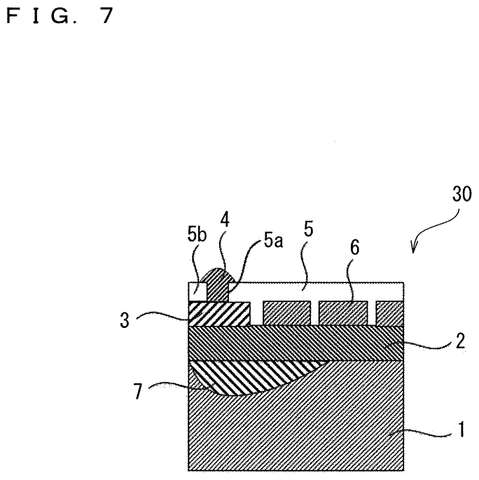

A semiconductor device 200 according to Embodiment 2 will be described with reference to FIGS. 6 and 7. FIG. 6 is a schematic top view of the semiconductor device 200 according to Embodiment 2. FIG. 7 is a schematic cross-sectional view of the semiconductor device 200 according to Embodiment 2. FIG. 7 illustrates a cross-sectional view taken along an alternate long and short dashed line A-A in FIG. 6. A dotted line in FIG. 6 represents the gate line 3 covered with the protective film 5 and a conductor.

In the semiconductor device 200 according to Embodiment 2, the gate pad portion 4 is a conductor electrically connected to the gate line 3. As illustrated in FIGS. 6 and 7, the conductor is disposed on the gate line 3. Embodiment 2 differs from Embodiment 1 in that not the gate line 3 itself but the conductor separately disposed on the gate line 3 functions as the gate pad portion 4.

Although the conductor is preferably disposed on the entirety of the four sides of the gate line 3 as illustrated in FIG. 6, the conductor should be disposed on the entirety of at least one side of the gate line 3. The conductor may be, for example, solder.

As illustrated in FIGS. 6 and 7, it is preferred to form the opening 5a by opening a part of the protective film 5 disposed on the front surface of the termination region 30 and dispose the conductor on the gate line 3 exposed by the opening 5a to allow the conductor to function as the gate pad portion 4. As illustrated in FIG. 7, the conductor is preferably formed thicker than the front surface of the protective film 5. This enables bonding on the conductor without through the opening 5a. Since the width of the opening 5a should be large enough to connect the gate line 3 to the conductor, the width of the opening 5a can be smaller than that according to Embodiment 1.

The semiconductor device 200 according to Embodiment 2 is structured in such a manner. Allowing the conductor separately disposed on the gate line 3 to function as the gate pad portion 4 and disposing the conductor on the entirety of at least one side of the gate line 3 increase a region in which bonding is possible, with respect to the entire perimeter of the semiconductor device 100. Thus, flexibility of assembling the semiconductor device can be increased, similarly to Embodiment 1.

Furthermore, using the conductor as the gate pad portion 4 can reduce the dimensions of the termination region 30 more than those according to Embodiment 1 in which the gate line 3 itself is the gate pad portion 4. When the gate line 3 itself is used as the gate pad portion 4, a gate pad region depends on the dimensions of the gate line 3. In contrast, in a structure using a conductor as the gate pad portion 4, the conductor can be formed by using the front surface of the termination region 30 with a withstanding voltage retention structure such as the field plates 6. Since a gate pad region does not depend on the dimensions of the gate line 3, the gate line 3 can be formed with a conventional width, and the dimensions of the termination region 30 can be reduced more than those according to Embodiment 1. In other words, the semiconductor device 200 according to Embodiment 2 can be downsized more than that according to Embodiment 1.

Next, a method of manufacturing the semiconductor device 200 according to Embodiment 2 will be described. The method of manufacturing the semiconductor device 200 according to Embodiment 2 differs from that according to Embodiment 1 by a part of the gate line formation process and a part of the gate pad portion formation process. The following will describe the differences in the gate line formation process and the gate pad portion formation process from those of Embodiment 1 in detail.

In Embodiment 2, the gate pad portion 4 is a conductor. A method of forming the conductor on the gate line 3 will be hereinafter described as an example.

First, the gate line formation process will be described. Similarly to Embodiment 1, the gate line 3 is formed above the upper surface of the semiconductor substrate 1. Forming the gate line 3 wider than conventional ones allows the gate line 3 to function as a gate pad in Embodiment 1, whereas the gate line 3 itself does not function as a gate pad in Embodiment 2. Thus, the gate line 3 may be formed with a conventional width.

Next, the gate pad portion formation process will be described. A method of forming the opening 5a in the protective film 5 disposed on the front surface of the termination region 30 to form the gate pad portion 4 will be described as an example of the gate pad portion formation process. First, the protective film 5 is formed on the front surface of the termination region 30. The protective film 5 is formed in, for example, CVD. Next, the opening 5a is formed by etching a portion of the protective film 5 which is formed on the gate line 3. Forming the opening 5a to reach the upper surface of the gate line 3 exposes the gate line 3, and a conductor is formed on the exposed gate line 3. Since the aforementioned conductor is electrically connected to the gate line 3, the conductor can function as the gate pad portion 4. The width of the conductor should be large enough to enable bonding, and may be appropriately set according to, for example, the thickness of a bonding wire.

The protective film 5 on the entirety of one side of the gate line 3 is opened, and the conductor is formed on the entirety of at least one side of the gate line 3. Preferably, the protective film 5 on the entirety of the four sides of the gate line 3 is opened, and the conductor is formed on the entirety of the four sides of the gate line 3.

Next, a modification of Embodiment 2 will be described with reference to FIGS. 8 and 9. FIG. 8 is a schematic top view of a semiconductor device according to the modification. FIG. 9 is a schematic cross-sectional view of the semiconductor device according to the modification. FIG. 9 illustrates a cross-sectional view of a cross section taken along an alternate long and short dashed line A-A in FIG. 8. Dotted lines in FIG. 8 represent the gate line 3 covered with the protective film 5 and a conductor.

As illustrated in FIGS. 8 and 9, the protective film 5 is disposed on the front surface of the termination region 30 in the modification of Embodiment 2. As illustrated in FIG. 8, the conductor may be formed by extending onto the protective film 5 in a direction away from the active region 20, using a surface region of the termination region 30. This can increase a region in which bonding is possible in a width direction of the gate line 3, and further increase flexibility of assembly. Since the bonding is possible in a position away from the active region 20, interference with the active region 20 in mounting the semiconductor device hardly occurs. Thus, safety can be increased.

As illustrated in FIG. 9, the first protective film 5b closer to the active region 20 may be formed thicker than other portions of the protective film 5 on the gate line 3. The conductor may be formed outside the first protective film 5b by extending onto other portions of the protective film 5 in a direction away from the active region 20. When the conductor is formed on the protective film 5 by extending in the direction away from the active region 20, forming the first protective film 5b thicker than the other portions of the protective film 5 can prevent the conductor from flowing inside the active region 20. Thus, the conductor can be easily formed only in the termination region 30.

The structures described in Embodiments are examples of the details of the present disclosure, and can be combined with other known arts. Furthermore, Embodiments and the modifications can be combined. A part of the structures can be omitted or changed without departing from the spirit and scope of the disclosure.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device including a semiconductor substrate having an active region that is rectangular in a top view, and a termination region around the active region, the semiconductor device comprising:
a gate electrode formed on an upper surface of the semiconductor substrate in the active region; and
a gate line formed above the upper surface of the semiconductor substrate in the termination region, the gate line being electrically connected to the gate electrode,
wherein the gate line is rectangular in a top view, and surrounds the active region,
the gate line includes a gate pad portion for connecting the gate electrode to an external portion through bonding, and
the gate pad portion is disposed on an entirety of at least one side of the gate line.

2. The semiconductor device according to claim 1,
wherein the gate pad portion is the gate line itself.

3. The semiconductor device according to claim 2, further comprising
a protective film on a front surface of the termination region,
the protective film having an opening formed by opening a part of the protective film,
wherein the gate line exposed by the opening is the gate pad portion.

4. The semiconductor device according to claim 1,
wherein the gate pad portion is a conductor disposed on the gate line and electrically connected to the gate line.

5. The semiconductor device according to claim 4, further comprising
a protective film on a front surface of the termination region,
the protective film having an opening formed by opening a part of the protective film,
wherein the conductor is disposed on the gate line exposed by the opening.

6. The semiconductor device according to claim 5,
wherein the conductor is formed by extending onto the protective film in a direction away from the active region.

7. The semiconductor device according to claim 6,
wherein the protective film includes a first protective film formed in a region closer to the active region on the gate line,
the first protective film is formed thicker than other portions of the protective film, and
the conductor is formed outside the first protective film by extending onto the other portions of the protective film in the direction away from the active region.

8. The semiconductor device according to claim 1,
wherein the gate pad portion is disposed on an entirety of four sides of the gate line.

9. The semiconductor device according to claim 1,
wherein the termination region has a withstanding voltage retention structure.

10. The semiconductor device according to claim 1,
wherein the semiconductor substrate is made of silicon carbide.

11. The semiconductor device according to claim 1,
wherein the active region includes a semiconductor switching element, and
the switching element is a reverse-conducting insulated-gate bipolar transistor.
